(19) United States
(12) Patent Application Publication
(10) Pub. No.: US 2012/0217575 A1
(43) Pub. Date: Aug. 30, 2012

(54) METHOD FOR MANUFACTURING SEMICONDUCTOR DEVICE AND SEMICONDUCTOR DEVICE

(75) Inventor: Tetsuo Matsuda, Ishikawa-ken (JP)

(73) Assignee: Kabushiki Kaisha Toshiba, Tokyo (JP)

(21) Appl. No.: 13/238,525

(22) Filed: Sep. 21, 2011

(30) Foreign Application Priority Data
Feb. 28, 2011 (JP) 2011-042606

(51) Int. Cl. H01L 21/336; H01L 29/78

(52) U.S. Cl. 257/330; 438/270; 257/E29.262; 257/E21.41

(57) ABSTRACT

According to one embodiment, a method is disclosed for manufacturing semiconductor device. The method can include preparing a semiconductor layer having a drain layer, and a drift region provided from a surface to an inside of the drain layer, the drift region having a first trench extending from a surface to an inside of the drift region. The method can include implanting impurities into the drift region through an opening of the first trench to form a source region for an exposed face of the drift region exposed on an inside wall of the first trench, and implanting impurities into the drift region through the opening of the first trench to form a base region between the source region and the drift region. The method can include forming gate electrode.

### CROSS-REFERENCE TO RELATED APPLICATIONS

This application is based upon and claims the benefit of priority from the prior Japanese Patent Application No. 2011-042606, filed on Feb. 28 2011; the entire contents of which are incorporated herein by reference.

### FIELD

Embodiments described herein relate generally to a method for manufacturing semiconductor device and a semiconductor device.

### BACKGROUND

As a structure for increasing the channel density in field-effect type transistors having a MOS (Metal Oxide Semiconductor) channel structure (hereinafter, a semiconductor device), there is a three-dimensional type structure.

In semiconductor devices of the three-dimensional type structure, each of a source region, a base region and a drain region is extended in a direction approximately perpendicular to the major surface of a semiconductor substrate, and, further, a gate electrode of a trench type is provided. In semiconductor devices of such structure, the channel region is formed in a direction approximately parallel to the major surface of the semiconductor substrate, and the channel region is also formed in the direction approximately perpendicular to the major surface of the semiconductor substrate. Consequently, the channel density is remarkably improved. In such semiconductor devices, the source region and the base region are generally formed by an epitaxial growth method.

However, the formation of the source region and the base region by the epitaxial growth method induces following problems. For example, in a process of doping impurities (such as an acceptor and a donor) in high concentrations to an epitaxial growth layer in a trench formed vertically, the growth rate of the epitaxial growth layer or the impurity concentration fluctuates in the depth direction of the trench. Consequently, an intended device structure may not be formed.

The occurrence of such phenomenon is considered to be derived from the difference in partial pressures between a silicon source gas and a doping gas used in the epitaxial growth method in the depth direction of the trench, etc. Moreover, the epitaxial growth method is a complex technique to thereby induce expensive facilities, a low productivity and an increase in the consumption of source gasses.

### BRIEF DESCRIPTION OF THE DRAWINGS

FIG. 1 is a schematic perspective view of a semiconductor device according to a first embodiment;

FIGS. 2A and 2B are schematic views of a semiconductor device according to the first embodiment;

FIGS. 3A to 3C are outline views for explaining the profile of impurity concentration of the semiconductor device according to the first embodiment;

FIGS. 4A to 4C are schematic perspective views for explaining the manufacturing process of the semiconductor device according to the first embodiment;

FIGS. 5A and 5B are schematic views for explaining the manufacturing process of the semiconductor device according to the first embodiment;

FIGS. 6A and 6B are schematic views for explaining the manufacturing process of the semiconductor device according to the first embodiment;

FIGS. 7A and 7B are schematic perspective views for explaining the manufacturing process of the semiconductor device according to the first embodiment;

FIGS. 8A and 8B are schematic cross-sectional views for explaining the manufacturing process of the semiconductor device according to a second embodiment;

FIGS. 9A to 9C are schematic perspective views for explaining the manufacturing process of the semiconductor device according to a third embodiment; and

FIGS. 10A to 10C are schematic perspective views for explaining the manufacturing process of the semiconductor device according to a fourth embodiment.

### DETAILED DESCRIPTION

In general, according to one embodiment, a method is disclosed for manufacturing semiconductor device. The method can include preparing a semiconductor layer having a drain layer of a first conductivity type and a drift region of a first conductivity type, the drift region provided from a surface of the drain layer to an inside of the drain layer, the drift region having a first trench extending from a surface of the drift region to an inside of the drift region. The method can include implanting impurities of a first conductivity type into the drift region through an opening of the first trench to form a source region of a first conductivity type for an exposed face of the drift region exposed on an internal surface of the first trench, and implanting impurities of a second conductivity type into the drift region through the opening of the first trench to form a base region of a second conductivity type between the source region and the drift region. The method can include forming a second trench from a part of the source region to a part of the drift region passing through the base region adjacent to the part of the source region in a direction approximately parallel to the surface of the drain layer. The method can include forming a gate electrode in the second trench via a gate insulating film.

Hereinafter, embodiments are explained while referring to the drawings. In explanations below, the same member is given the same numeral, and the explanation of a member once explained is omitted appropriately.

### First Embodiment

A semiconductor device manufactured by the method for manufacturing semiconductor device of the embodiment is explained.

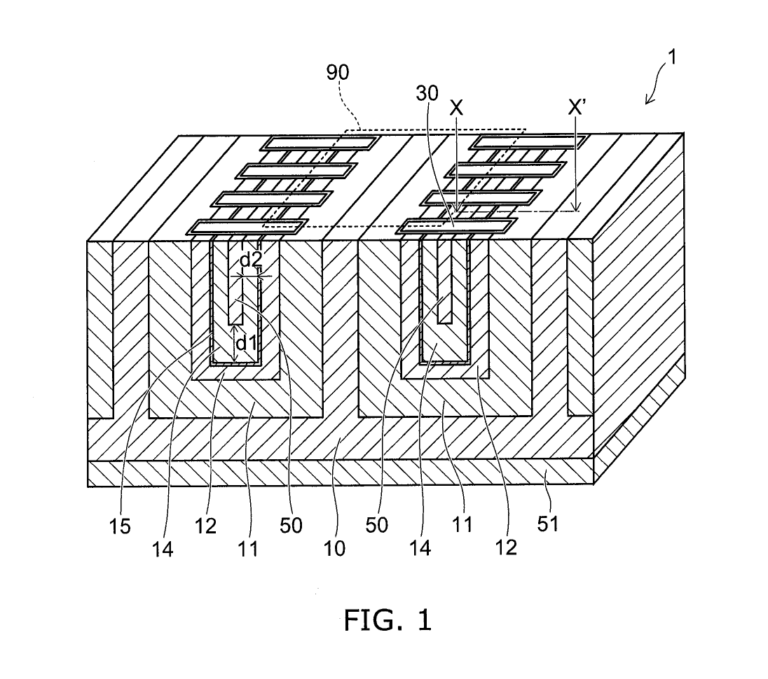

FIG. 1 is a schematic perspective view of a semiconductor device according to the first embodiment.

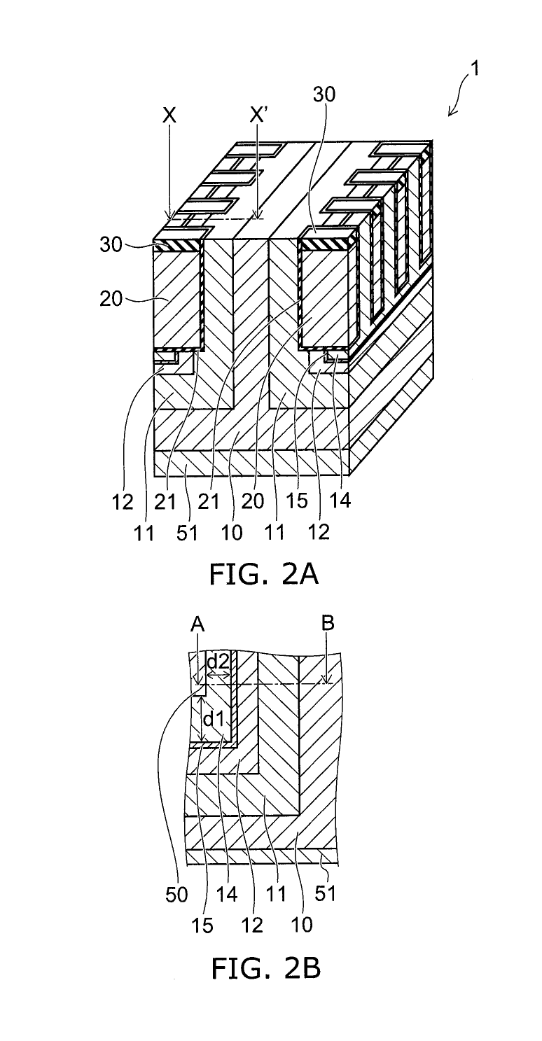

FIGS. 2A and 2B are schematic views of a semiconductor device according to the first embodiment. FIG. 2A is a schematic perspective view of a part surrounded by a region 90 in FIG. 1, and FIG.2B is a schematic cross-sectional view in the X-X′ position in FIG. 1.

A semiconductor device 1 illustrated in FIGS. 1 and 2 is a MOSFET (Metal Oxide Semiconductor Field Effect Transistor) of a three-dimensional type structure. FIG. 1 is a schematic perspective view of the semiconductor device according to the first embodiment, FIG. 2A is a schematic perspective view of a part surrounded by the region 90 in FIG. 1, and FIG. 2B is a schematic cross-sectional view in the X-X′ position in FIG. 1.

The semiconductor device 1 has a drain layer 10 of an n⁺ type (first conductivity type), and has a drift region 11 of an n-type (first conductivity type) provided selectively in the drain layer 10 from the surface to the inside of the drain layer 10. The semiconductor device 1 has a base region 12 of a p-type (second conductivity type) provided selectively in the drift region 11 from the surface to the inside of the drift region 11, and a source region 14 of an n⁺ type provided selectively in the base region 12 from the surface to the inside of the base region 12.

In the semiconductor device 1, a gate electrode 20 of a trench form is provided. The gate electrode 20 is extended until a part of the drift region 11 from a part of the source region 14 passing through the base region 12 adjacent to the part, in a direction approximately parallel to the major surface (the upper face or the lower face) of the drain layer 10. A gate insulating film 21 is provided between the gate electrode 20 and the drift region 11, between the gate electrode 20 and the base region 12, between the base region 12 and the source region 14, and between the gate electrode 20 and a source electrode 50. An interlayer insulating film 30 is provided on the gate electrode 20.

To the source region 14, the source electrode 50 is connected. To the lower face of the drain layer 10, a drain electrode 51 is connected. The source electrode 50 is provided from the surface to the inside of the source region 14.

Thickness d1 of the source region 14 contacting with the lower face of the source electrode 50 provided from the surface to the inside of the of the source region 14 is greater than thickness d2 of the source region 14 contacting with the side face of the source electrode 50 provided from the surface to the inside of the source region 14. A source wiring connected to the source electrode 50 (not shown) is provided on the surface side of the semiconductor device 1. Consequently, when the semiconductor device 1 is ON, the source region 14 of the trench d1 part has the most elevated potential due to the influence of the resistance of the source region 14 extending vertically. That is, the d1 part approaches the potential of the drain electrode, relative to the potential of the source electrode. The source region 14 of the d1 part is a region included in operable regions of MOSFET (source region/ base region/drift region/ drain layer). For the purpose of making the semiconductor device 1 to operate effectively, the above-mentioned potential elevation in the source region 14 gives harmful effects. For example, when the potential elevation occurs, sufficient current can not be flown to the d1 part and the reduction of the ON resistance of the semiconductor device 1 as a whole can not be achieved. Accordingly, the source region 14 of the d1 part desirably has a resistance as low as practical. In the embodiment, by employing ion implantation to be described later, it is possible to form the source region 14 in the d1 part that is higher in the concentration and deeper as compared with the source region 14 in the d2 part, to thereby eliminate the above-mentioned harmful effects and to realize the resistance reduction between the source region and the drain layer.

Moreover, as shown in FIG. 2B, there is provided a low-doped region (extension region) 15 of the first conductivity type having an impurity concentration lower than that in the source region 14 between the source region 14 and the base region 12.

The main component in the drain layer 10, the drift region 11, the base region 12, the source region 14, and the low-doped region 15 is, for example, silicon (Si). Impurity elements of the n-type (first conductivity type) include phosphorous (P), arsenic (As), etc. Impurity elements of the p-type (second conductivity type) include boron (B), etc.

The concentration of an n-type impurity in the drain layer 10 and the source region 14 is, for example, 5×10¹⁹ (atoms/cm³). The concentration of an n-type impurity in the drift region 11 is, for example, 2×10¹⁶ (atoms/cm³). The concentration of a p-type impurity in the base region 12 is, for example, 1×10¹⁸ (atoms/cm³).

The impurity concentration in the base region 12 in the semiconductor device 1 is a value obtained by subtracting the total number of n-type impurities from the total number of p-type impurities in the base region 12 and then dividing the resulting number by the volume of the base region 12. The impurity concentration in the source region 14 in the semiconductor device 1 is a value obtained by subtracting the total number of p-type impurities from the total number of n-type impurities in the source region 14 and then dividing the resulting number by the volume of the source region 14.

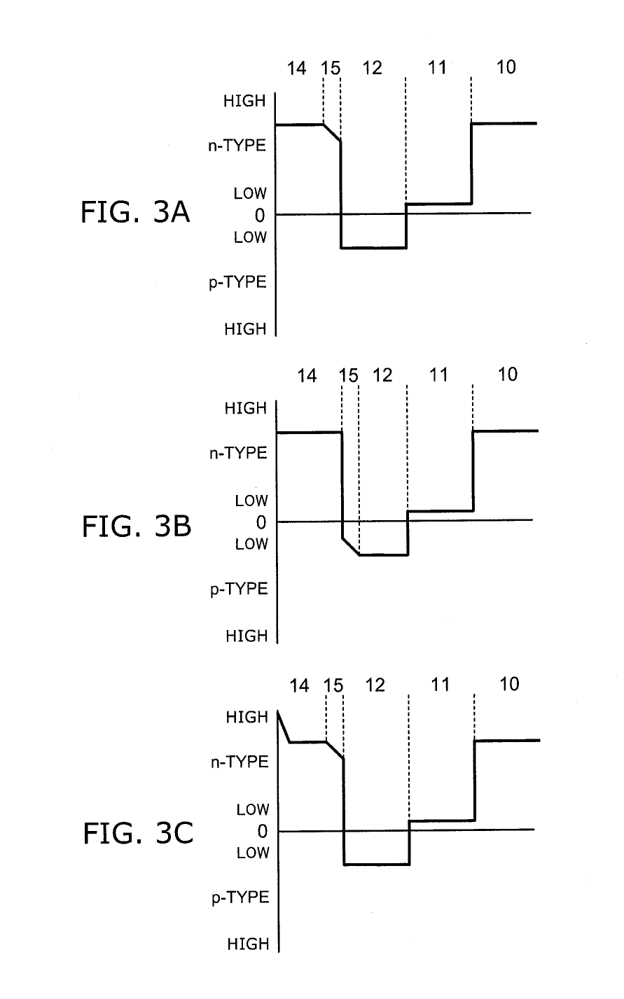

FIGS. 3A to 3C are outline views for explaining the profile of impurity concentration of the semiconductor device according to the first embodiment.

There are shown three kinds of profiles of impurity concentration, that is, FIGS. 3A to 3C. The horizontal axis of FIGS. 3A to 3C shows the position along A to B of the A-B line in FIG. 2B, that is, the positions of the source region 14, the low-doped region 15, the base region 12, the drift region 11 and the drain layer 10, and the vertical axis of FIGS. 3A to 3C shows the height of the impurity concentration. With regard to the height of the impurity concentration, while considering the center “0” as the boundary, on the up side from “0,” an upper side has a higher n-type impurity concentration, and, on the low side from “0,” a lower side has a higher p-type impurity concentration.

In the example shown in FIG. 3A, with regard to the profile of impurity concentration in the semiconductor device 1, the source region 14 contains an n-type impurity in a high concentration, and the base region 12 contains a p-type impurity in a low concentration. In the low-doped region 15, a gradient is formed, in which the concentration of the n-type impurity lowers from the interface between the source region 14 and the low-doped region 15 toward the interface between the base region 12 and the low-doped region 15. That is, the concentration of the n-type impurity contained in the low-doped region 15 (1×10¹⁹ (atoms/cm³)) is lower than the concentration of the n-type impurity contained in the source region 14 (5×10¹⁹ (atoms/cm³)). As described above, the low-doped region 15 of the first conductivity type having an impurity concentration lower than that in the source region 14 is formed between the source region 14 and the base region 12.

The formation of the low-doped region 15 moderates the electric field lying from the source region 14 toward the base region 12 to thereby suppress the implantation of hot carriers (electron, hole) into the gate insulating film 21. This induces hardly the deterioration, variation of the threshold, etc. of the gate insulating film 21 to be generated.

In the example shown in FIG. 3B, with regard to the profile of impurity concentration in the semiconductor device 1, the source region 14 contains an n-type impurity in a high concentration, and the base region 12 contains a p-type impurity in a low concentration. In the low-doped region 15, a gradient is formed, in which the concentration of the p-type impurity rises from the interface between the source region 14 and the low-doped region 15 toward the interface between the base region 12 and the low-doped region 15. That is, the concentration of the p-type impurity contained in the low-doped region 15 (2×10¹⁷ (atoms/cm³)) is lower than the concentration of the p-type impurity contained in the base region 12 (1×10¹⁸ (atoms/cm³)). As described above, the low-doped region 15 of the second conductivity type having an impurity concentration lower than that in the base region 12 is formed between the source region 14 and the base region 12.

In the example shown in FIG. 3C, the impurity concentration in the source region 14 on the source electrode 50 side may be made higher than the impurity concentration in the source region 14 on the base region 12 side. Such configuration more reduces the contact resistance between the source electrode 50 and the source region 14.

Meanwhile, configurations obtained by combining two or more of any of FIGS. 3A to 3C are also included in the embodiment.

According to the semiconductor device 1, the source region 14, the base region 12 and the low-doped region 15 are formed by ion implantation, and, therefore, the impurity concentration in the source region 14, the base region 12 and the low-doped region 15 can be controlled simply with a high accuracy.

Next, the manufacturing process of the semiconductor device according to the first embodiment will be explained.

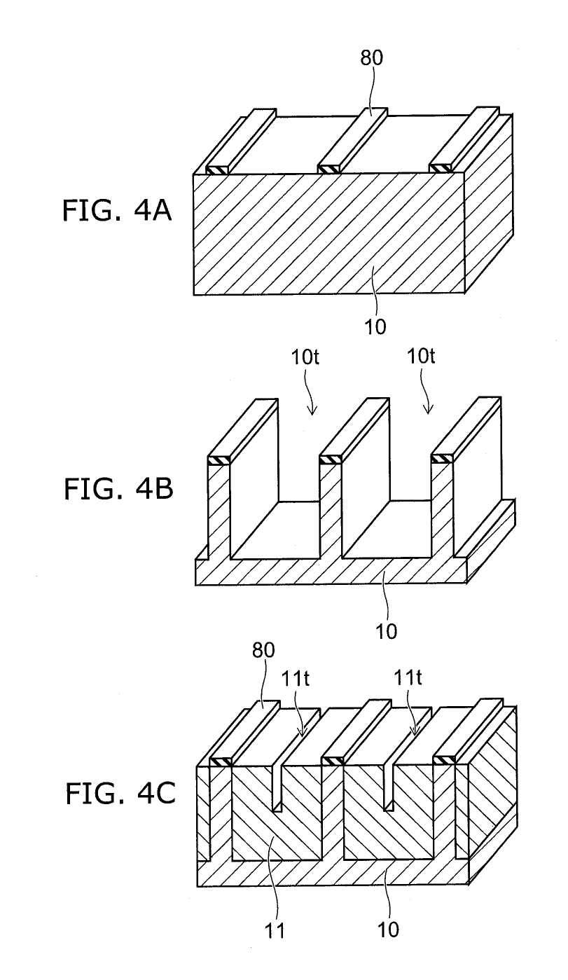

FIGS. 4A to 4C are schematic perspective views for explaining the manufacturing process of the semiconductor device according to the first embodiment.

First, as shown in FIG. 4A, after preparing the drain layer 10 that is a semiconductor substrate, a mask member 80 is formed selectively on the surface of the drain layer 10. The material of the mask member 80 is, for example, silicon oxide (SiO₂).

Next, as shown in FIG. 4B, while using the mask member 80 as a mask, the surface of the drain layer 10 is etched by reactive ion etching (RIE). This forms a trench 10t extending from the surface to the inside of the drain layer 10.

Next, as shown in FIG. 4C, in the trench 10t, the drift region 11 is formed by an epitaxial growth method. This induces the drift region 11 to grow from the surface of the drain layer 10 corresponding to the lower face of the trench 10t, and from the surface of the drain layer 10 corresponding to the inner face of the trench 10t.

In the first embodiment, not all the inside of the internal surface of the trench 10t is embedded with the drift region 11. For example, the drift region 11 is formed so that a trench (first trench) 11t extending from the surface toward the inside of the drift region 11 is left in the drift region 11. That is, the drift region 11 including the trench 11t is formed in the trench 10t. This prepares a semiconductor layer provided with the drift region 11 including the trench 11t, from the surface toward the inside of the drain layer 10. In other words, a semiconductor layer having the drain layer 10, and the drift region 11 provided from the surface toward the inside of the drain layer 10, the region 11 having the trench 11t extending from the surface toward the inside of the drift region 11 is provided.

The trench 11t has a depth of, for example, 15 μm. The trench 11t has a width (width in the d2 direction in FIG. 1) is, for example, 0.5 μm. That is, trench 11t has an aspect ratio of 30. After that, the mask member 80 is removed. Meanwhile, apart from the above example using a selective epitaxial growth by the mask member 80, a method, in which the drift region 11 is epitaxially grown non-selectively in the upper part of the trench 10t and the drain layer 10 in FIG. 4B and then the epitaxial layer in excess regions is removed, may be employed.

Meanwhile, the drift region 11 may be formed by a thermal diffusion method, instead of the epitaxial growth method.

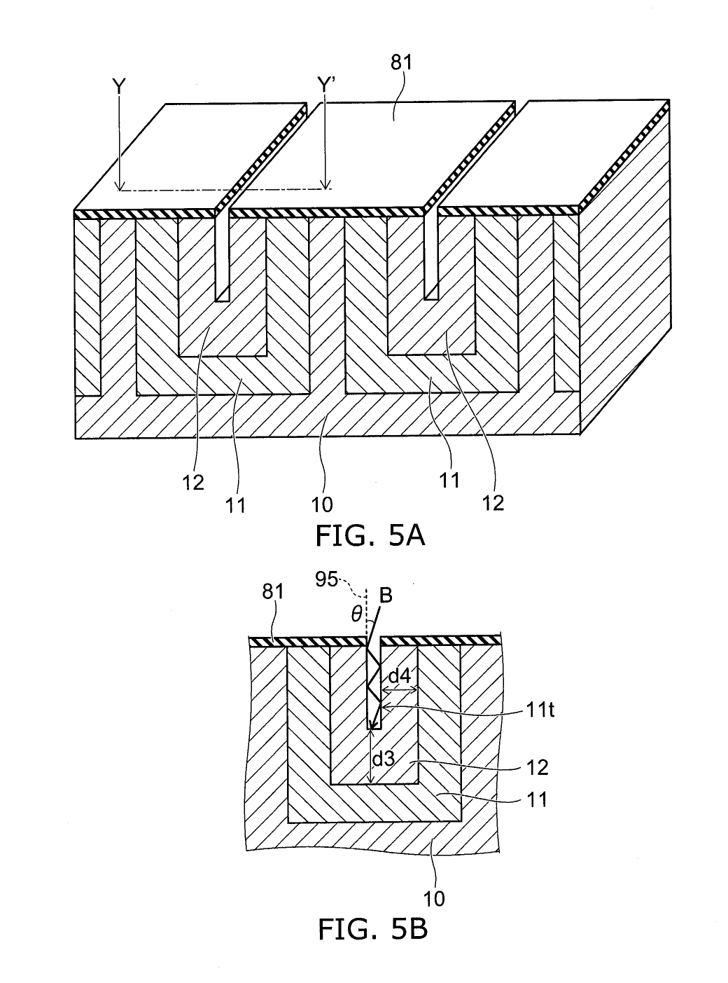

FIGS. 5A and 5B are schematic views for explaining the manufacturing process of the semiconductor device according to the first embodiment. 5A is a schematic perspective view, and 5B is a schematic cross-sectional view along Y-Y′ in 5A.

As shown in FIGS. 5A and 5B, a mask member 81 is formed selectively on the drain layer 10 and the drift region 11 so that the trench 11t is exposed. Alternatively, the mask member 81 may be formed by patterning a mask member formed uniformly on the major surface of a semiconductor layer using lithography etc. The material of the mask member 81 is, for example, silicon oxide (SiO₂). Subsequently, into the drift region 11 exposed on the internal surface of the trench 11t, impurities such as boron (B) are introduced. The introduction of the impurities is performed by the ion implantation.

In the ion implantation, impurities are implanted into the drift region 11 exposed on the internal surface of the trench 11t, inclined by an angle θ (tilt angle θ) from a reference axis 95 in a direction that is perpendicular to the major surface of the drain layer 10. The angle θ is, for example, 2° to 10°, more preferably 7°.

In the ion implantation, on the inside surface of the trench 11t, a part of the impurities is implanted into the inside surface, and the other impurities are rebounded repeatedly from the inside surface of the trench 11t to arrive eventually at the bottom face of the trench 11t. As the result, even if the trench 11t has a high aspect ratio, the impurity is implanted not only into the inside surface of the trench 11t but also into the surface of the drift region 11 that is the bottom face of the trench 11t in a high concentration.

Moreon, in the ion implantation, a so-called counter ion implantation is performed. For example, such amount of a p-type impurity (such as boron (B)) that reverses the n-type conductivity of the drift region 11 to the p-type conductivity is implanted into the surface of the drift region 11. That is, a p-type impurity of such number that exceeds the number of the n-type impurity contained in the surface of the drift region 11 is implanted into the surface of the drift region 11.

Ion implantation conditions in this step are as follows.

The setting of ion implantation conditions are determined in consideration of the trench form, surface roughness, subsequent heat treatment conditions, etc. For example, they are determined after obtaining sufficient preliminary data by a process simulator, and trial and error experiments by actual trials.

An example is as follows, ion-type: B⁺, acceleration voltage: 1 MeV, dose quantity: 3×10¹⁵ (atoms/cm²), and tilt angle η: 7°.

The penetration depth of the impurity into the bottom part of the trench 11t is 1.76 μm and the presumed penetration depth into the side wall of the trench 11t is 0.21 μm (=1.76 μm×sin 7°). By subsequent thermal diffusion, the presumed final concentration in the base region 12 of the side wall of the trench 11t becomes 1×10¹⁸ (atoms/cm³).

Another example is as follows, ion-type: B⁺⁺⁺ (triple charge), acceleration voltage: 500 KeV, dose quantity: 2×10¹⁵ (atoms/cm²), tilt angle θ: 10°. In this case, the penetration depth of the impurities into the bottom part of the trench 11t is 2.3 μm, and the presumed penetration depth into the side wall of the trench 11t is 0.40 μm (=2.3 μm×sin 10°).

Consequently, for the exposed face of the drift region 11 exposed on the internal surface of the trench 11t, the base region 12 is formed. Since the impurities are implanted in a high concentration even into the bottom face of the trench 11t, the thickness d3 of the base region 12 contacting with the bottom face of the trench 11t becomes larger than the thickness d4 of the base region 12 contacting with the inside surface of the trench 11t.

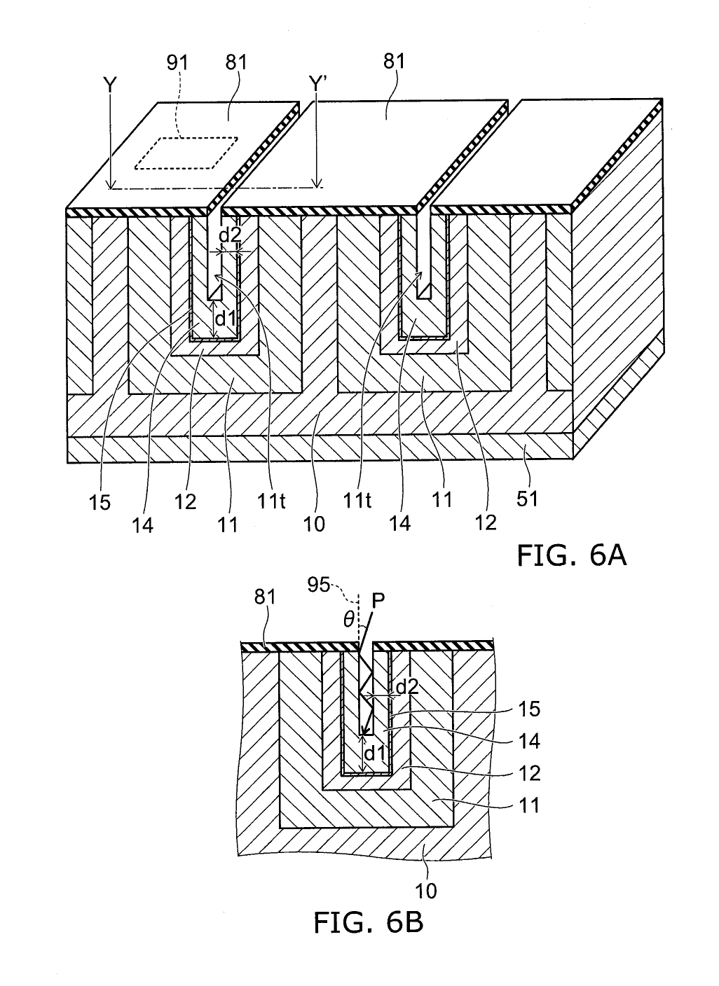

FIGS. 6A and 6B are schematic views for explaining the manufacturing process of the semiconductor device according to the first embodiment. 6A is a schematic perspective view, and 6B is a schematic cross-sectional view along Y-Y′ in 6A.

As shown in FIGS. 6A and 6B, into the base region 12 exposed on the internal surface of the trench 11t, for example, impurities such as phosphorous (P) are introduced. The introduction of the impurities is performed by the ion implantation.

In the ion implantation, impurities are implanted into the base region 12 exposed on the internal surface of the trench 11t, inclined by an angle θ (tilt angle θ) from the reference axis 95 in a direction that is perpendicular to the major surface of the drain layer 10. The angle θ is, for example, 2° to 10°, more preferably 7°.

In the ion implantation, on the inside surface of the trench 11t, a part of the impurities is implanted into the inside surface, and the other impurities are rebounded repeatedly from the inside surface of the trench 11t to arrive eventually at the bottom face of the trench 11t. As the result, even if the trench 11t has a high aspect ratio, the impurities are implanted into the surface of the base region 12 that is the bottom face of the trench 11t in a high concentration.

In the ion implantation, the counter ion implantation is performed. For example, such amount of an n-type impurity (such as phosphorous (P) or arsenic (As)) that reverses the p-type conductivity of the base region 12 to the n-type conductivity is implanted into the surface of the base region 12.

Ion implantation conditions in this step are as follows.

In this case, too, the setting of ion implantation conditions are determined in consideration of the trench form, surface roughness, subsequent heat treatment conditions, etc. For example, they are determined after obtaining sufficient preliminary data by a process simulator, and trial and error experiments by actual trials. For example, in order to achieve a flat concentration distribution as the diagram shown in FIG. 3, ion implantations may be performed multiple times while dividing the dose and changing the acceleration voltage, or energy may be swept.

In order to form a high concentration layer in the outermost face in FIG. 3C, the use of such heavy ion as As is preferable. Because, when the heavy ion is used, it penetrates shallowly and does not diffuse thereafter.

An example is as follows, ion-type: P⁺, acceleration voltage: 200 KeV, dose quantity: 2×10¹⁷ (atoms/cm²), and tilt angle θ: 10°. In this case, the penetration depth of the impurity into the bottom part of the trench 11t is 0.25 μm, and the presumed penetration depth into the side wall of the trench 11t is 0.043 μm (=0.25 μm×sin 10°). By subsequent thermal diffusion, the presumed final concentration in the source region 14 of the side wall of the trench 11t becomes 5×10¹⁹ (atoms/cm³).

Another example is as follows, ion-type: As⁺, acceleration voltage: 200 KeV, dose quantity: 8×10¹⁶ (atoms/cm²), tilt angle θ: 7°. In this case, the penetration depth of the impurities into the bottom part of the trench 11t is 0.11 μm, and the presumed penetration depth into the side wall of the trench 11t is 0.013 μm (=0.11×sin 7°). By subsequent thermal diffusion, the presumed final concentration in the source region 14 of the outermost face of the trench side wall becomes 8×10¹⁹ (atoms/cm³).

Consequently, for the exposed face of the base region 12 exposed on the internal surface of the trench 11t, the source region 14 is formed. Since the impurity is implanted in a high concentration even into the bottom face of the trench 11t, thickness d1 of the source region 14 contacting with the bottom face of the trench 11t becomes thicker than thickness d2 of the source region 14 contacting with the inside surface of the trench 11t.

Moreover, the low-doped region 15 having a lower impurity concentration than the concentration in the source region 14 is formed between the source region 14 and the base region 12. Or, as shown in FIG. 3B, the low-doped region 15 of the second conductivity type having a lower impurity concentration than the concentration of the base region 12 may be formed between the source region 14 and the base region 12. Furthermore, as shown in FIG. 3C, the source region 14 may be formed so that the impurity concentration of the source region 14 on a source electrode 50 side, the electrode 50 being to be formed in a following-process, becomes higher than the impurity concentration of the source region 14 on the base region 12 side. After that, the mask member 81 is removed. The mask member 81 is removed, for example, by etching. After removing the mask member 81, surfaces of the source region 14, the low-doped region 15, and the base region 12 are exposed.

As described above, in processes shown in FIGS. 5A and 5B, and FIGS. 6A and 6B, impurities such as phosphorous (P) and arsenic (As) are implanted into the drift region 11 through an opening of the trench 11t and the source region 14 is formed for the exposed face of the drift region 11 exposed on the internal surface of the trench 11t, and impurities such as boron (B) are implanted into the drift region 11 through the opening of the trench 11t to thereby form the base region 12 between the source region 14 and the drift region 11. Here, “opening” is defined as the opening at a top position of the trench 11t.

In the first embodiment, impurities such as boron (B) are implanted into the drift region 11 exposed on the internal surface of the trench 11t to thereby form the base region 12 for the exposed face of the drift region 11 exposed on the internal surface of the trench 11t. After that, into the base region 12 exposed on the internal surface of the trench 11t, impurities such as phosphorous (P) and arsenic (As) are implanted to thereby form the source region 14 for the exposed face of the base region 12 exposed on the internal surface of the trench 11t.

Meanwhile, the drift region 11 may be rotated in the direction perpendicular to the reference axis 95 when performing the ion implantation of impurities such as boron (B) and phosphorous (P). Or, such processes may be repeatedly practiced that the drift region 11 is rotated from the state shown in FIG. 5B or FIG. 6B in 180° in the direction perpendicular to the reference axis 95 and ion implantation is performed, and that the region 11 is furthermore rotated in 180° in the direction perpendicular to the reference axis 95 and the ion implantation is performed.

Next, the process of forming the gate electrode 20 is explained. The formation process of the gate electrode 20 is explained while taking a region 91 in FIG. 6A as an example.

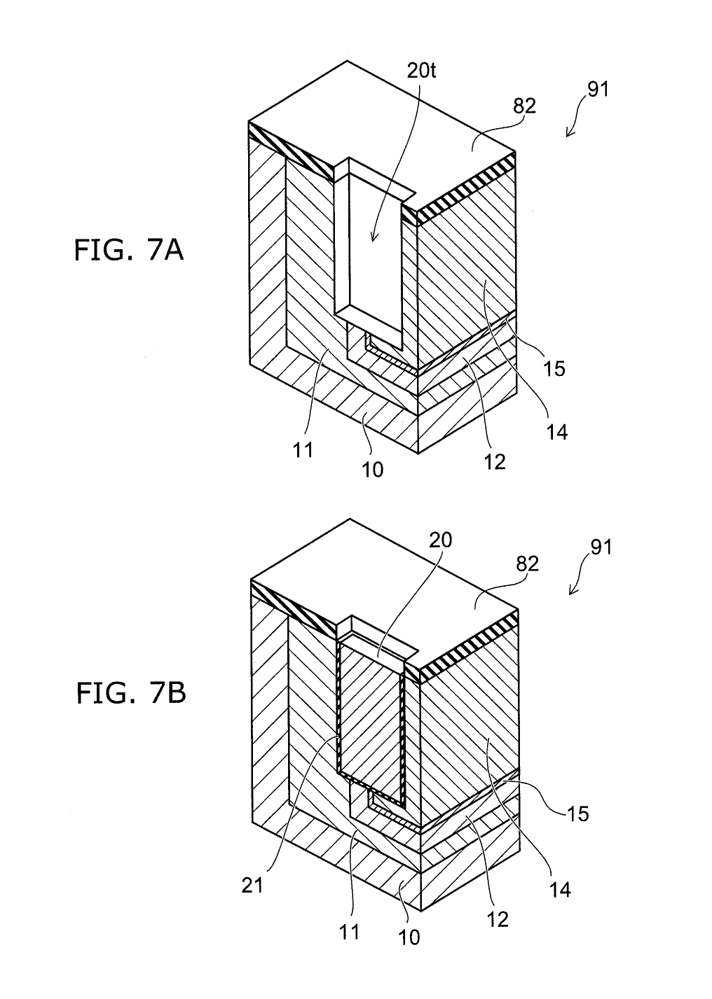

FIGS. 7A and 7B are schematic perspective views for explaining the manufacturing process of the semiconductor device according to the first embodiment.

As shown in FIG. 7A, a mask member 82 for forming a gate electrode is formed. The material of the mask member 82 is, for example, silicon oxide (SiO₂). A part of each of the drift region 11, the low-doped region 15, the base region 12 and the source region 14 which is opened from the mask member 82 is selectively subjected to etching. This forms a trench (second trench) 20t for a part of each of the drift region 11, the base region 12, the low-doped region 15 and the source region 14. The trench 20t starts from a part of the source region 14, passes through the base region 12 adjacent to the part of the source region 14, and is extended until the part of the drift region 11, in a direction approximately parallel to the major surface of the drain layer 10. Subsequently, an internal surface of the trench 20t is exposed to an oxidizing atmosphere under high temperatures.

As the result of the exposure to an oxidizing atmosphere, as shown in FIG. 7B, the gate insulating film 21 is formed on the side face and the bottom face of the trench 20t. Subsequently, in the trench 20t, the gate electrode 20 is formed via the gate insulating film 21 by CVD (Chemical Vapor Deposition). This forms the gate electrode 20 in a trench form from surfaces of base region 12, a part of the source region 14 adjacent to the base region 12 via the low-doped region 15 and a part of the drift region 11 on the side opposite to the part of the source region 14 to the inside, while sandwiching the base region 12. The material of the gate electrode 20 is, for example, polysilicon (poly-Si). After forming the gate electrode 20, the mask member 82 is removed.

After that, as shown in FIG. 1, the source electrode 50 connected electrically to the source region 14 and the base region 12, and the drain electrode 51 connected electrically to the drain layer 10 are formed. The material of the source electrode 50 is, for example, polysilicon doped with an n-type impurity, metal silicide, etc. The source electrode 50 is embedded into the trench 11t by CVD. The material of the drain electrode 51 is, for example, copper (Cu). The drain electrode 51 is formed by sputtering or plating.

In the embodiment explained above, an epitaxial growth method is not used in the formation of the source region 14 and the base region 12. That is, in the semiconductor device 1, the source region 14 and the base region 12 are formed by the ion implantation. Consequently, as compared with a process of forming the source region 14 and the base region 12 by an epitaxial growth method, the source region 14 and the base region 12 can be manufactured at low cost.

According to the embodiment, the adjustment of the ion implantation conditions (such as acceleration voltage and dose quantity) can adjust more simply and easily the impurity concentration profiles of the source region 14, the low-doped region 15 and the base region 12 in the direction approximately parallel to the major surface of the drain layer 10.

For example, in order to lower the contact resistance between the source electrode 50 and the source region 14, the impurity concentration of the surface of the source region 14 on the source electrode 50 side can be raised simply and easily.

When the source region 14 of such high concentration is formed by an epitaxial growth, in some instances, many crystal defects are generated in the source region 14. For example, the diameter of such impurities as phosphorous (P) and arsenic (As) is different from the diameter of a silicon atom. When such impurity different in the diameter is incorporated in an epitaxial growth layer with a high concentration, in some instances, strain is generated in the epitaxial growth layer. As the result, in the epitaxial growth, in some instances, the source region 14 contains many defects.

Moreover, in the epitaxial growth method, the control of film thickness and film quality is, in some instances, more difficult, as compared with the ion implantation. For example, the film thickness in the trench depth direction, and the impurity concentration in the trench depth direction may become uneven. As the result, in some instances, the element manufacturing becomes difficult, or complex and expensive investment in facilities is necessary. Moreover, in some instances, the epitaxial growth method induces high cost because of low productivity and high consumption of source gasses.

For example, in a process for doping impurities (such as acceptor and donor) in a high concentration into the epitaxial growth layer, when the epitaxial growth layer is grown in the trench formed vertically, in some instances, the growth rate of the epitaxial growth layer varies, or the impurity concentration in the epitaxial growth layer varies in the trench depth direction. Therefore, in some instances, an intended device structure can not be attained. It is considered that such phenomenon occurs due to the difference in partial pressures of a source gas (such as silane-based gas) and a doping gas used in the epitaxial growth method in the trench depth direction, etc.

According to the embodiment, the drift region 11 is previously formed, and, after that, the source region 14, the base region 12, etc. are formed by the ion implantation. According to such method, it becomes possible to suppress simply and easily the impurity diffusion from the source region 14 to the base region 12. For example, the adjustment of ion implantation conditions (such as acceleration voltage and dose quantity) enables the impurity concentration of the source region 14 located near the interface between the source region 14 and the base region 12 to be lowered simply and easily. Moreover, according to the embodiment, the impurity concentration in the low-doped region 15 may also be adjusted simply and easily.

According to the embodiment, the mask member 81 is provided, the trench 11t is formed, and, after that, the source region 14, the low-doped region 15 and the base region 12 are formed collectively by ion implantation. After that, a process, in which the mask member 81 is removed from the surface of the source region 14, the low-doped region 15 and the base region 12 to thereby show the surfaces of the source region 14, the low-doped region 15 and the base region 12, is gone through. Consequently, after forming the source region 14, the low-doped region 15 and the base region 12, the polishing of the surfaces of the source region 14, the low-doped region 15 and the base region 12 by CMP (Chemical Mechanical Polishing) is not necessary. As the result, the manufacturing process of the semiconductor device 1 becomes simpler and easier. As described above, according to the embodiment, semiconductor devices with better quality can be manufactured at low cost.

Meanwhile, the embodiment includes manufacturing processes shown below, in addition to the above-mentioned manufacturing processes.

For example, a semiconductor substrate, which has drain layer 10 and the drift region 11 provided from the surface to the inside of the drain layer 10 and, furthermore, the base region 12 provided from the surface to the inside of the drift region, is prepared previously. In the base region 12, trench 11t extending from the surface toward the inside thereof lies. Each of the drain layer 10, the drift region 11 and the base region is formed by an epitaxial growth and thermal diffusion method.

Subsequently, an n-type impurity is implanted into the base region 12 through the opening of the trench 11t to thereby form the source region for the exposed face of the base region 12 exposed on the internal surface of the trench 11t.

In the ion implantation of the case, too, the counter ion implantation is practiced. That is, an n-type impurity (such as phosphorous (P) or arsenic (As)) is implanted into the surface of the base region 12 in such quantity that reverses a p conductivity type of the base region 12 to an n-type. The manufacturing process, too, forms the semiconductor layer shown in FIG. 6B.

### Second Embodiment

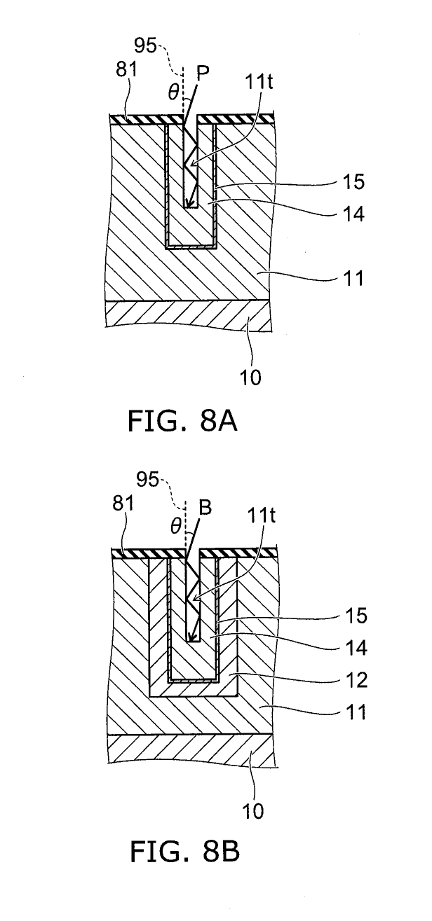

FIGS. 8A and 8B are schematic cross-sectional views for explaining the manufacturing process of the semiconductor device according to a second embodiment.

In the second embodiment, as shown in FIG. 8A, impurities such as phosphorous (P) and arsenic (As) are implanted into the drift region 11 exposed on the internal surface of the trench 11t to thereby form the source region 14 for the exposed face of the drift region exposed on the internal surface of the trench 11t. Furthermore, the low-doped region 15 may be formed.

After that, as shown in FIG. 8B, impurities such as boron (B) are implanted into the drift region 11 while passing through the source region 14 exposed on the internal surface of the trench 11t to thereby form the base region 12 between the source region 14 and the drift region 11.

That is, in the second embodiment, the procedure for forming the source region 14 and the base region 12 in the first embodiment is reversed. Also through such manufacturing process, the semiconductor device 1 can be manufactured.

### Third Embodiment

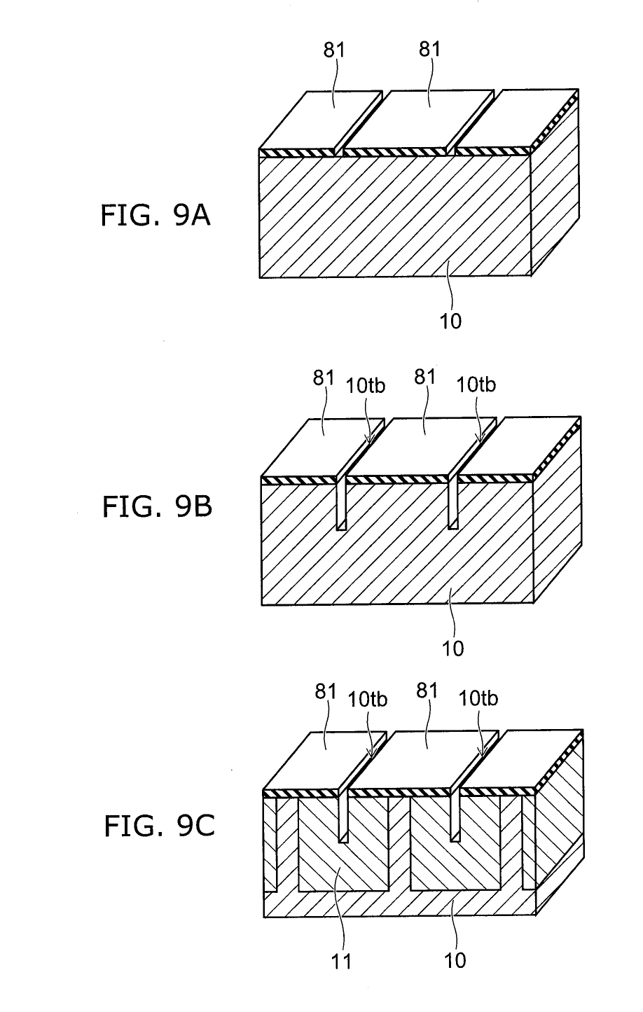

FIGS. 9A to 9C are schematic perspective views for explaining the manufacturing process of the semiconductor device according to a third embodiment.

In the third embodiment, as shown in FIG. 9A, after preparing the drain layer 10 that is a semiconductor substrate, the mask member 81 is formed selectively on the drain layer 10.

Next, as shown in FIG. 9B, the drain layer 10 shown from the mask member 81 is etched by RIE to thereby form, in the drain layer 10, a trench (third trench) 10tb extending from the surface toward the inside of the drain layer 10.

Next, as shown in FIG. 9C, into the drain layer 10 exposed on the internal surface of the trench 10tb, impurities such as phosphorous (P) and arsenic (As) are implanted to form the drift region 11 for the exposed face of the drain layer 10 exposed on the internal surface of the trench 10tb.

After that, by continuing processes shown in FIGS. 5 to 7, the semiconductor device 1 can be manufactured. Such manufacturing process is also included in the embodiment.

### Fourth Embodiment

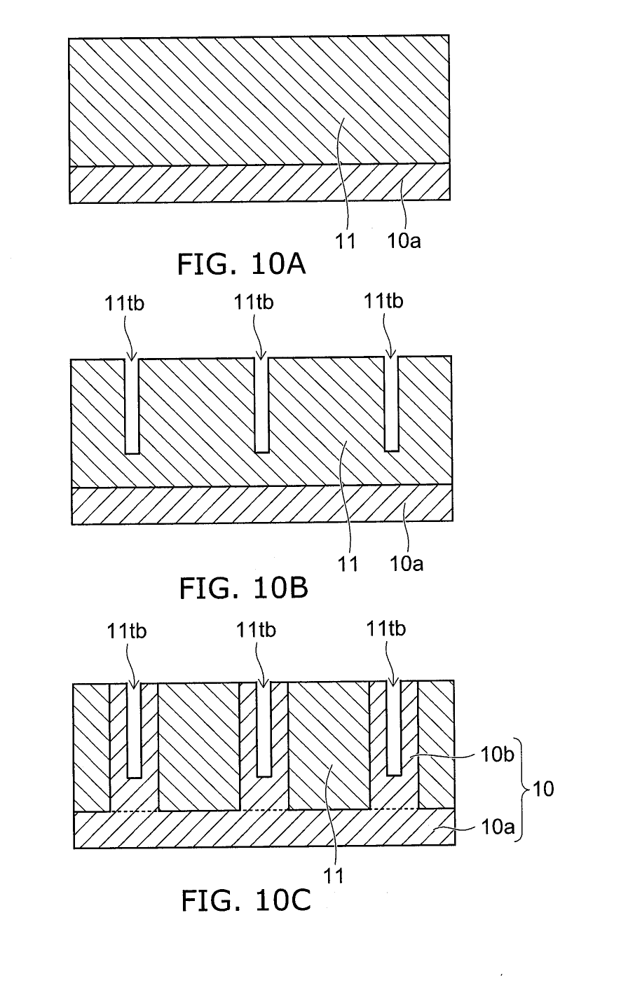

FIGS. 10A to 10C are schematic perspective views for explaining the manufacturing process of the semiconductor device according to a fourth embodiment.

In the fourth embodiment, as shown in FIG. 10A, a semiconductor stacked body, in which the drift region 11 is formed on a first drain part 10a, is prepared.

Next, as shown in FIG. 10B, a trench (fourth trench) 11tb extending from the surface to the inside of the drift region 11 is formed. The depth of the trench 11tb is deeper than that of the trench 11t, and is, for example, 20 μm. The width of the trench 11tb is 0.5

Next, as shown in FIG. 10C, impurities such as phosphorous (P) and arsenic (As) are implanted into the drift region 11 through an opening of the trench 11tb. This forms a second drain part 10b connected to the first drain part 10a, from the surface to the bottom of the drift region 11.

The drain layer 10 includes the first drain part 10a and the second drain part 10b. The second drain part 10b is connected to the first drain part 10a, provided extending approximately perpendicular to the major surface of the first drain part 10a. After that, into the trench 11tb, polysilicon, metal silicide, or the like may be embedded. Such manufacturing process, too, can form a semiconductor layer in which the drift region 11 is formed from the surface to the inside of the drain layer 10.

Moreover, it is also possible to form the trench 11tb at the same time as forming the trench 11t in the first and second embodiments, and to perform the formation process of the second drain part 10b at the same time as performing the formation process of the source region 14. By practicing these at the same time, the number of the manufacturing processes is remarkably reduced to thereby lower the production cost.

Hereinabove, embodiments are described with reference to specific examples. However, the embodiments are not limited to these specific examples. That is, examples obtained by appropriately adding design modifications to these specific examples by a person skilled in the art are included within the embodiment as long as the features of the embodiment are included. Respective elements and the arrangement, material, condition, shape, size, etc. thereof that are given to respective specific examples are not limited to those that are exemplified, but may be changed appropriately. For example, MOSFET is used for the explanation in the example, but, in a similar manner, IGBT (Insulated Gate Bipolar Transistor) is also practicable. In this case, the source is replaced with an emitter, and the drain is replaced with a collector.

Respective elements given to aforementioned respective embodiments can be combined so far as the technology permits, and forms obtained by combining these are included in the embodiment so far as they include the characteristics of the embodiment. In addition, a person skilled in the art may conceive various changed examples and modified examples, and those changed examples and modified examples, too, are understood to belong in the range of embodiments. For example, after the ion implantation process, suitably, a heat treatment may be given.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing semiconductor device, comprising:
preparing a semiconductor layer having a drain layer of a first conductivity type and a drift region of a first conductivity type, the drift region provided from a surface of the drain layer to an inside of the drain layer, the drift region having a first trench extending from a surface of the drift region to an inside of the drift region;
implanting impurities of a first conductivity type into the drift region through an opening of the first trench to form a source region of a first conductivity type for an exposed face of the drift region exposed on an internal surface of the first trench, and implanting impurities of a second conductivity type into the drift region through the opening of the first trench to form a base region of a second conductivity type between the source region and the drift region;
forming a second trench from a part of the source region to a part of the drift region passing through the base region adjacent to the part of the source region in a direction approximately parallel to the surface of the drain layer; and
forming a gate electrode in the second trench via a gate insulating film.

2. The method according to claim 1, wherein the impurity of the first conductivity type is entered into the first trench tilted by an angle of 2° to 10° from a direction perpendicular to a major surface of the drain layer.

3. The method according to claim 1, wherein the impurity of the second conductivity type is entered into the first trench tilted by an angle of 2° to 10° from a direction perpendicular to a major surface of the drain layer.

4. The method according to claim 1, wherein:
the impurities of the second conductivity type are implanted into the drift region exposed on the internal surface of the first trench to form the base region for the exposed face of the drift region exposed on the internal surface of the first trench, and
after forming the base region, the impurities of the first conductivity type are implanted into the base region exposed on the internal surface of the first trench to form the source region for the exposed face of the base region exposed on the internal surface of the first trench.

5. The method according to claim 1, wherein:
the impurities of the first conductivity type are implanted into the drift region exposed on the internal surface of the first trench to form the source region for the exposed face of the drift region exposed on the internal surface of the first trench, and
after forming the source region, the impurities of the second conductivity type are implanted into the drift region passing through the source region exposed on the internal surface of the first trench to form the base region between the source region and the drift region.

6. The method according to claim 1, wherein a low-doped region of the first conductivity type having a lower impurity concentration than a impurity concentration of the source region is formed between the source region and the base region.

7. The method according to claim 1, wherein a low-doped region of the second conductivity type having a lower impurity concentration than a impurity concentration of the base region is formed between the source region and the base region.

8. The method according to claim 1, wherein the impurity concentration of the source region on a side of the source electrode side is higher than the impurity concentration of the source region on a side of the base region side.

9. The method according to claim 1, wherein:
a third trench extending from a surface of the drain layer to an inside of the drain layer is formed for the drain layer, and
after forming the third trench, the impurities of the first conductivity type are implanted into the drain layer exposed on an internal surface of the third trench to form the drift region for the exposed face of the drain layer exposed on the internal surface of the third trench.

10. The method according to claim 1, wherein:
the drain layer comprises a first drain part and second drain part, the second drain part is connected to the first drain part and extends approximately perpendicular to a major surface of the first drain part from the first drain,
a semiconductor stacked body is prepared, the drift region is formed on the first drain part in the semiconductor stacked body,
after preparing the semiconductor stacked body, a fourth trench extending from a surface of the drift region to an inside of the drift region is formed, and
the impurities of the first conductivity type are implanted into the drift region through an opening of the fourth trench to form the second drain part connected to the first drain part from a surface of the drift region to a bottom of the drift region.

11. A method for manufacturing semiconductor device, comprising:
preparing a semiconductor layer having a drain layer of a first conductivity type, a drift region of a first conductivity type, and a base region of a second conductivity type, a drift region provided from a surface of the drain layer to an inside of the drain layer, a base region provided from a surface of the drift region to an inside of the drift region, the base region having a first trench extending from a surface of the base region to an inside of the base region;
implanting impurities of a first conductivity type into the base region through an opening of the first trench to form a source region of a first conductivity type for an exposed face of the base region exposed on an internal surface of the first trench;
forming a second trench from a part of the source region to a part of the drift region passing through the base region adjacent to the part of the source region, in a direction approximately parallel to the surface of the drain layer; and
forming a gate electrode in the second trench via a gate insulating film.

12. The method according to claim 11, wherein a low-doped region of the first conductivity type having a lower impurity concentration than a impurity concentration of the source region is formed between the source region and the base region.

13. The method according to claim 11, wherein a low-doped region of the second conductivity type having a lower impurity concentration than a impurity concentration of the base region is formed between the source region and the base region.

14. The method according to claim 11, wherein the impurity concentration of the source region on a side of the source electrode side is higher than the impurity concentration of the source region on a side of the base region side.

15. The method according to claim 11, wherein:
a third trench extending from a surface of the drain layer to an inside of the drain layer is formed for the drain layer, and
after forming the third trench, the impurities of the first conductivity type are implanted into the drain layer exposed on an internal surface of the third trench to form the drift region for the exposed face of the drain layer exposed on the internal surface of the third trench.

16. The method according to claim 11, wherein:
the drain layer comprises a first drain part and a second drain part, the second drain part is connected to the first drain part and extends approximately perpendicular to a major surface of the first drain part from the first drain,
a semiconductor stacked body is prepared, the drift region is formed on the first drain part in the semiconductor stacked body,
after preparing the semiconductor stacked body, a fourth trench extending from a surface of the drift region to an inside of the drift region is formed, and
the impurities of the first conductivity type are implanted into the drift region through an opening of the fourth trench to form the second drain part connected to the first drain part from a surface of the drift region to a bottom of the drift region.

17. A semiconductor device, comprising:
a drift region of a first conductivity type provided selectively in a drain layer of a first conductivity type from a surface of the drain layer to an inside of the drain layer;
a base region of a second conductivity type provided selectively in the drift region from a surface of the drift region to an inside of the drift region;
a source region of a first conductivity type provided selectively in the base region from a surface of the base region to an inside of the base region; and
a gate electrode in a trench extending until a part of the drift region from a part of the source region passing through a base region adjacent to the part of the source region, in a direction approximately parallel to a major surface of the drain layer; wherein
a part of the source electrode is provided from a surface of the source region to an inside of the source region, and
the thickness of the source region contacting with a lower face of the source electrode provided from the surface of the source region to the inside of the source region is larger than a impurity concentration of the source region contacting with a side face of the source electrode provided from the surface of the source region to the inside of the source region.

18. The device according to claim 17, wherein a low-doped region of a first conductivity type having a lower impurity concentration than that of the source region is formed between the source region and the base region.

19. The device according to claim 17, wherein a low-doped region of a second conductivity type having a lower impurity concentration than a impurity concentration of the base region is formed between the source region and the base region.

20. The device according to claim 17, wherein the impurity concentration of the source region on a side of the source electrode side is higher than the impurity concentration of the source region on a side of the base region side.
